(19) United States
(12) Patent Application Publication
(10) Pub. No.: US 2025/0200140 A1
(43) Pub. Date: Jun. 19, 2025

(54) APPARATUS AND METHOD FOR ACCELERATING ACTIVATION FUNCTION BASED ON PIM

(71) Applicant: UIF (University Industry Foundation), Yonsei University, Seoul (KR)

(72) Inventors: Joon-Sung YANG, Seoul (KR); Jae Hyung KO, Seoul (KR); Jun Yong OH, Seoul (KR)

(21) Appl. No.: 18/979,107

(22) Filed: Dec. 12, 2024

(30) Foreign Application Priority Data
Dec. 13, 2023 (KR) 10-2023-0180602

(51) Int. Cl. G06F 17/17; H03K 19/20

(52) U.S. Cl. CPC G06F 17/17; H03K 19/20

(57) ABSTRACT

The present disclosure provides an apparatus and method for accelerating activation function, wherein the application range of the activation function is divided into multiple intervals, and an interval indicator is obtained indicating an interval in which an input value is included by using multiple interval detection operators to select one approximate activation function among multiple approximate activation functions approximated in each interval, an approximate activation function being set for the interval designated by the interval indicator is obtained, and the input value is input into the obtained approximate activation function to obtain an activation operation result. According to the apparatus and method for accelerating activation function of of the present disclosure, not only can an interval according to an input value for selecting an approximate activation function be easily determined, but also the operation can be accelerated by performing activation operations simultaneously in parallel.

### CROSS-REFERENCE TO RELATED APPLICATIONS

This application claims priority under 35 U.S.C. § 119 (a) to Korean Patent Application No. 10-2023-0180602, filed on Dec. 13, 2023, with the Korean Intellectual Property Office, the disclosure of which is incorporated herein in its entirety by reference.

### BACKGROUND

### 1. Technical Field

The present disclosure relates to an apparatus and method for accelerating activation function, and more particularly, to an apparatus and method for accelerating activation function based on PIM.

### 2. Description of the Related Art

Artificial neural networks typically consist of multiple layers, each comprising multiple kernels that receive input or output from the previous layer and perform neural network operations.

FIG. 1 is a schematic diagram showing the operations performed in the kernel of an artificial neural network.

As shown in FIG. 1, the kernel receives input or a plurality of values u₁ to u_{d} transmitted from the previous layer, calculates a weighted sum

$$x = {\sum }_{j = 1}^{d} {u}_{j} {w}_{j}$$

of the received plurality of values u₁ to u_{d} and a plurality of weights w₁ to w_{d} determined by learning, and inputs the result of the weighted sum to the activation function f, and outputs the result of the activation operation of the activation function for the result of the weighted sum as a kernel output y. Here, the activation function f is a function that is specified in advance when configuring the artificial neural network.

Conventional artificial neural networks primarily used simple activation functions, such as ReLU (Rectified Linear Unit). However, recent artificial neural networks such as the Transformer model or the DCNN (Deep Convolutional Neural Network) model increasingly employ activation functions with high complexity. In addition, as the complexity of the activation function increases, the computational cost of the artificial neural network increases.

### SUMMARY OF THE INVENTION

An object of the present disclosure is to provide an apparatus and method for accelerating activation function, which can reduce computational cost and accelerate operations by using approximate activation functions approximated by intervals according to input values for operations of high-complexity activation functions.

Another object of the present disclosure is to provide an apparatus and method for accelerating activation function, which can easily determine intervals based on input values for selecting approximate activation functions.

Still another object of the present disclosure is to provide an apparatus and method for accelerating activation function, which can obtain multiple approximate activation functions for each of multiple input values in a memory and accelerate the computations by performing parallel processing.

According to one embodiment of the present disclosure, an apparatus for accelerating activation function is provided, which comprises: a memory; and a controller, wherein the application range of the activation function is divided into multiple intervals, and the controller obtains an interval indicator indicating an interval in which an input value is included by using multiple interval detection operators to select one approximate activation function among multiple approximate activation functions approximated in each interval, obtains an approximate activation function set for the interval designated by the interval indicator, and inputs the input value into the obtained approximate activation function to obtain an activation operation result.

The interval detection operator may be configured as an operator that inverts some bits of an input value and performs a logical AND operation according to the bit length and bit value of a bit pattern that values included in each interval have in common, when the application range of the activation function is divided into multiple intervals by multiple boundary points expressed in floating point numbers.

The interval indicator may be a one-hot segment vector composed of a 1-bit interval detection value obtained by operating the input value with each of multiple interval operators for each interval.

The multiple approximate activation functions may be obtained by searching for a point where the error between the activation function and an approximate function in which the activation function is approximated by linear interpolation in the interval divided so far in the application range of the activation function is maximum, setting points whose absolute value is a power of 2 among the closest points to the searched point as boundary points and adding them to a boundary point list, if the set boundary points are already included in the boundary point list, setting the midpoint between the two closest power of 2 points to the searched point as a boundary point and adding it to the boundary point list, if both the selected boundary point and the midpoint are boundary points that are already included in the boundary point list, setting the midpoint between the closest point to the searched point in the boundary point list and the searched point as a boundary point and adding it to the boundary point list, and linearly interpolating the activation function in each interval divided by the multiple boundary points.

The apparatus for accelerating activation function may be implemented with PIM (Processing-in-memory).

The controller may obtain the interval indicator for each of the multiple input values by performing an interval detection operation in parallel for each of the multiple input values stored in the memory using the multiple interval detection operators.

The controller may obtain coefficients and biases of approximate activation functions selected by each of the multiple interval indicators according to multiple input values by combining logical operations of bit values for each bit position of the multiple interval indicators stored in the memory.

The controller may obtain the bit values for each bit position of the coefficient and the bias by performing NOR operations on the bit values for each bit position specified in the interval indicators.

The apparatus for accelerating activation function may be implemented with a nonvolatile memory-based PIM, and the controller may perform reduced-NOR operations that first performs and stores NOR operations on two bits when performing NOR operations on three or more multi-bits, and then overlaps and records NOR operations on the bit values of other bits.

The input values may be obtained by calculating a weighted sum of weights and at least one value applied to multiple kernels provided in the artificial neural network, respectively.

According to another embodiment of the present disclosure, a method for accelerating activation function is provided, which is performed by a controller in an apparatus including a memory and the controller, comprising the steps of: obtaining an interval indicator indicating an interval in which an input value is included by using multiple interval detection operators to select one approximate activation function among multiple approximate activation functions approximated in each interval where the application range of the activation function is divided into multiple intervals; obtaining an approximate activation function set for the interval designated by the interval indicator; and inputting the input value into the obtained approximate activation function to obtain an activation operation result.

The apparatus and method for accelerating activation function of the present disclosure utilize an approximate activation function approximated by an interval according to an input value for the operation of a high-complexity activation function, and can easily determine an interval according to an input value for selecting an approximate activation function. In addition, by obtaining multiple approximate activation functions for each of multiple input values, the operation can be accelerated by performing activation operations simultaneously in parallel.

### BRIEF DESCRIPTION OF THE DRAWINGS

FIG. 1 is a schematic diagram showing the operations performed in the kernel of an artificial neural network.

FIG. 2 shows a configuration of the apparatus for accelerating activation function according to one embodiment divided according to the operation performed.

FIG. 3 is a diagram for explaining the concept of approximation of the activation function.

FIG. 4 is a diagram for explaining a technique for dividing intervals of an activation function based on the VBG algorithm.

FIG. 5 shows a method for setting multiple interval detection operators for detecting intervals according to input values based on interval information.

FIG. 6 shows a method for obtaining an interval indicator indicating an interval corresponding to an input value using interval detection operators.

FIG. 7 is a diagram for explaining a method for obtaining coefficients and biases of an approximate activation function based on an interval indicator.

FIG. 8 shows an example of a PIM-based implementation of an apparatus for accelerating activation function.

FIGS. 9A and 9B are a diagram for explaining a reduced-NOR operation in PIM.

FIG. 10 shows a method for accelerating activation function according to one embodiment.

FIG. 11 is a diagram for explaining a computing environment including a computing device according to one embodiment.

### DETAILED DESCRIPTION OF THE INVENTION

Hereinafter, specific embodiments according to the embodiments of the present disclosure will be described with reference to the drawings. The following detailed description is provided to assist in a comprehensive understanding of the methods, devices and/or systems described herein. However, this is only an example and the present invention is not limited thereto.

In describing the embodiments of the present disclosure, when it is determined that detailed descriptions of known technology related to the present disclosure may unnecessarily obscure the gist of the embodiments, the detailed descriptions thereof will be omitted. The terms used below are defined in consideration of functions in the present disclosure, but may be changed depending on the customary practice or the intention of a user or operator. Thus, the definitions should be determined based on the overall content of the present specification. The terms used herein are only for describing the embodiments, and should not be construed as limitative. Unless the context clearly indicates otherwise, the singular forms are intended to include the plural forms as well. It should be understood that the terms “comprises,” “comprising,” “includes,” and “including,” when used herein, specify the presence of stated features, numerals, steps, operations, elements, or combinations thereof, but do not preclude the presence or addition of one or more other features, numerals, steps, operations, elements, or combinations thereof. In addition, terms such as “ . . . unit”, “ . . . er/or”, “module” and “block” described in the specification means a unit for processing at least one function or operation, which may be implemented by hardware or software or a combination of hardware and software.

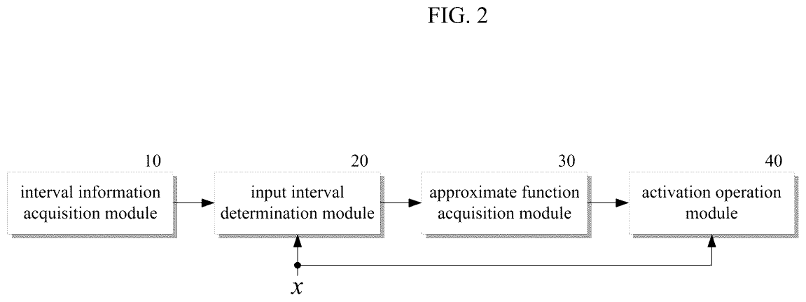

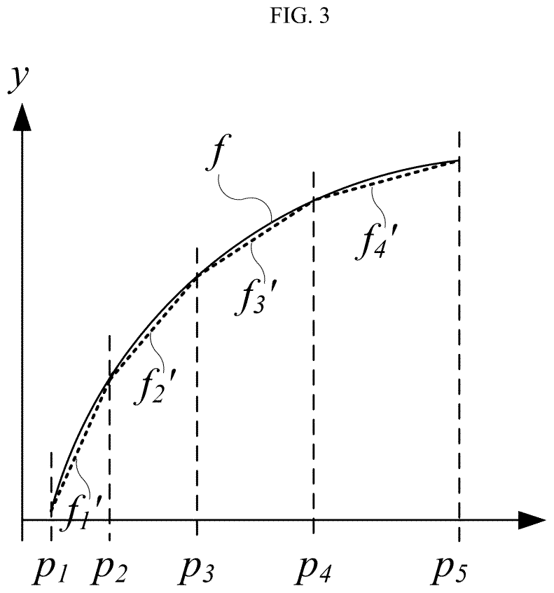

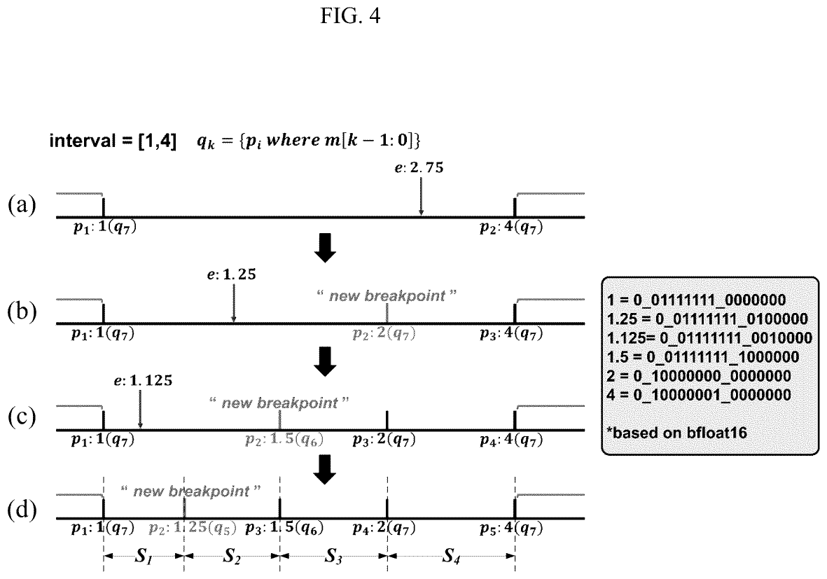

FIG. 2 shows a configuration of the apparatus for accelerating activation function according to one embodiment divided according to the operation performed, FIG. 3 is a diagram for explaining the concept of approximation of the activation function, and FIG. 4 is a diagram for explaining a technique for dividing intervals of an activation function based on the VBG algorithm.

Referring to FIG. 2, the apparatus for accelerating activation function may include an interval information acquisition module 10, an input interval determination module 20, an approximate function acquisition module 30, and an activation operation module 40.

The interval information acquisition module 10 acquires interval information for each of multiple intervals to which multiple approximate activation functions that approximate the activation function f are applied.

In the present disclosure, the apparatus for accelerating activation function reduces computational cost by using multiple approximate activation functions f₁′, f₂′, f₃′ and f₄′ in which a complicated activation function f in an artificial neural network is divided into intervals and approximated by a simple linear function, as shown in FIG. 3.

However, since the activation function is divided into intervals and approximated, the approximate activation functions f₁′, f₂′, f₃′ and f₄′ are different for each interval, so the apparatus for accelerating activation function must perform the activation operation by selecting the approximate activation function of the interval corresponding to the input value x. Accordingly, the interval information acquisition module 10 acquires interval information for each interval determined when the activation function f is approximated by multiple approximate activation functions.

Here, the activation function f may be approximated based on the PWL (piecewise linear) approximation technique, as shown in FIG. 3. The PWL approximation technique may divide the activation function f to be approximated into multiple intervals, sample the activation function f in each of the divided intervals, and obtain an approximated function by linearly interpolating between the sampled points. Accordingly, linearly approximated approximate activation functions f₁′, f₂′, f₃′ and f₄′ are obtained differently for each interval. Here, the approximate activation functions f₁′, f₂′, f₃′ and f₄′ for each interval may have the form of f′=ax+b for the input x.

In this way, when dividing the range to which the activation function f is applied into multiple intervals and approximating it, the multiple intervals may be divided to have uniform sizes, but as in FIG. 3, the multiple intervals may be divided to have non-uniformly different sizes. When dividing the multiple intervals into uniform sizes, the interval to which the input value x is applied can be easily determined, but the error between the approximation function f approximated in each interval and the activation function f increases. On the other hand, when dividing the multiple intervals into non-uniform sizes according to the activation function f, the error between the activation function f and the approximate function f decreases, but the sizes of each interval become different.

Here, the apparatus for accelerating activation function uses multiple approximate activation functions f₁′, f₂′, f₃′ and f₄′ obtained by approximating the activation function f based on the PWL approximation technique, which is a non-uniform interpolation technique, to improve accuracy. In addition, the activation function f may be divided into multiple intervals where the range over which the activation function f is applied is non-uniform according to the Variable Breakpoint Generation (hereinafter, VBG) algorithm in the process of approximating the activation function f based on the PWL approximation technique. In the VBG algorithm, the number of boundary points to be used to divide the intervals, i.e. the number of intervals, is used as a constraint.

In the VBG algorithm, the boundary points are sequentially repeatedly generated up to a specified number within a specified range. Specifically, the VBG algorithm extracts an approximate function f in which the activation function f is approximated by linear interpolation in the currently divided intervals. Then, the maximum error point e indicating the input value x where the error between the activation function f and the approximate function f is maximized is searched first. Then, considering the floating point representation, the value closest to the searched maximum error point e and which has the minimum number of bits in the part that must be expressed as a mantissa in the floating point representation is generated as a boundary point (Breakpoint) that divides the interval. At this time, the boundary point may be set so that the number of bits in the mantissa is the minimum at a level that can be distinguished from other previously set boundary points.

Specifically, among the points closest to the maximum error point, the point whose absolute value is a power of 2 may be set as a boundary point first and added to the boundary point list. However, if the boundary point is already set as a boundary point and included in the boundary point list, two points in the power of 2 closest to the maximum error point may be selected from the boundary point list, and the midpoint between the two selected points may be set as the boundary point. In addition, if the midpoints of the power of 2 and power of 2 are preset and are in the boundary point list, the point closest to the maximum error point may be selected from the boundary point list, and the midpoint between the maximum error point and the selected point may be added to the boundary point list.

Afterwards, the process of extracting the approximation function f again from the interval divided according to the set boundary point and searching for the maximum error point e with the maximum error value to generate boundary points is repeated. The VBG algorithm repeatedly generates boundary points until the number of generated boundary points reaches the specified number, thereby dividing the range to which the activation function f is applied into multiple intervals.

Hereinafter, the operation of the VBG algorithm will be specifically described with reference to the example illustrated in FIG. 4. In FIG. 4, it is assumed that the range to which the activation function f is applied is a range of input values x from 1 to 4, and the interval information acquisition module 10 additionally generates three boundary points within the range to divide it into four intervals S₁, S₂, S₃ and S₄.

In addition, here, as an example, it is assumed that the activation function uses a floating point representation in the bf16 (brain floating point16) format. Bf16 is a 16-bit floating point format developed for artificial neural networks, consisting of a sign bit of 1, an exponent bit of 8, and a mantissa bit of 7. Bf16 has lower precision than the existing 32-bit floating point format, but it can support small memory capacity and fast operations, and it has higher precision due to the extended number of exponent bits compared to the existing 16-bit floating point format, making it a suitable floating point representation format for artificial neural networks.

Referring to (a) of FIG. 4, first, the initial boundary points p₁ and p₂ indicating the boundaries of the specified range are identified. The bf16 format representation for each of the initial boundary points p₁ and p₂ is 1=“0_01111111_0000000” and 4=“0_10000001_0000000” as shown on the right side of FIG. 4. Here, “_” is a separator to distinguish between the sign, exponent, and mantissa.

Then, the maximum error point e is searched for, which represents the input value x that maximizes the error between the linearly interpolated approximate activation function and the activation function f between the initial boundary points p₁ and p₂. In (a), it is shown that when the input value x is 2.75, the error between the approximate activation function and the activation function f is maximized, and therefore the maximum error point e is e=2.75. However, in the VBG algorithm, considering the floating point representation format (bf16 in this case), the point where the mantissa part expressed in 7 bits in bf16 is minimized is generated as the boundary point. In other words, the boundary point is generated so that the 7 bits corresponding to the mantissa part are not utilized as much as possible.

Accordingly, as in (b), 2 with the mantissa part omitted from the maximum error point e is generated as a boundary point p₂, and the bf16 expression for the boundary point p₂ is 2=“0_10000000_0000000”. Since the boundary point p₂ generated here is distinguishable from the initial boundary points p₁ and p₃ even if the part corresponding to 0.75, which should be expressed as a mantissa in the maximum error point e of 2.75, is omitted, it is set to 2.

In FIG. 4, qₖ is the non-expression mantissa bit information, which is data that expresses the case where the lower k bits of the 7 bits corresponding to the mantissa part in the bf16 representation at each boundary point pᵢ are 0. In the three boundary points p₁, p₂ and p₃ shown in (b), the 7 bits corresponding to the mantissa are not utilized, so the non-expression mantissa bit information qₖ is all q₇.

Then, since the entire range (1 to 4) is divided into two intervals by the boundary point p₂ generated in (b), the maximum error point e is searched again which represents the input value x that maximizes the error between the linearly interpolated approximate activation function for each of the two divided intervals and the activation function f. In (b), the maximum error point e is shown as e=1.25. When the maximum error point (e) is 1.25, the closest point that does not utilize the 7 bits corresponding to the mantissa part is 1. However, 1 is already set as the boundary point p₁, and the other closest point, 2, is also already set as the boundary point p₂. Therefore, the closest point that does not utilize the 7 bits corresponding to the mantissa part as much as possible is 1.5, and thus 1.5 (0_01111111_1000000) is generated as a new boundary point p₂ as shown in (c). At this time, the number of bits of the mantissa that are not utilized at the generated boundary point p₂ is 6 (k=6), so the non-expression mantissa bit information q₆ is also indicated.

After that, in (c), the new maximum error point e is e=1.125, and the closest point that does not utilize the 7 bits corresponding to the mantissa part as much as possible is 1.25. Therefore, as shown in (d), 1.25 (0_01111111_0100000) is generated as a new boundary point p₂, and since the number of bits of the mantissa that are not utilized is 5 (k=5), the non-expression mantissa bit information q₅ is also indicated.

That is, in the example of FIG. 4, the VBG algorithm may divide the range of 1 to 4 into four non-uniform intervals S₁ to S₄ of 1 to 1.25, 1.25 to 1.5, 1.5 to 2, and 2 to 4 by additionally generating three boundary points p₂, p₃ and p₄ with values of 1.25, 1.5, and 2, respectively, between the range of 1 to 4. In addition, by linearly interpolating the values of the activation function f sampled at each of the five boundary points p₁ to p₅ including the initial boundary points, four approximate activation functions f₁′ to f₄′ corresponding to each of the four non-uniform intervals S₁ to S₄ can be obtained.

Accordingly, the interval information acquisition module 10 acquires interval information for the set intervals S₁ to S₄ in the process of approximating the activation function f with multiple approximate activation functions f₁′ to f₄′. Here, the interval information S₁ to S₄ may be acquired based on the boundary points p₁ to p₅ expressed in the bf16 format, and has a unique floating point representation for each interval.

In addition, the interval information acquisition module 10 may acquire an approximate activation function f₁′ to f₄′ in which the activation function f in each interval is approximated by linear interpolation.

As the activation function f is approximated by multiple interval-wise approximate activation functions f₁′ to f₄′, the apparatus for accelerating activation function must determine an interval corresponding to the input value x among the multiple divided intervals, acquire an approximate activation function approximated in the determined interval, and perform an operation.

Accordingly, the input interval determination module 20 sets multiple interval detection operators to detect intervals according to input values x based on common bit patterns of values included in each interval, among the multiple intervals divided according to boundary points p₁ to p₅ acquired as interval information, and determines an interval corresponding to the input value x using the set multiple interval detection operators to obtain an interval indicator.

When multiple boundary points are generated based on the VBG algorithm, and the range to which the activation function f is applied is divided into multiple intervals S₁ to S₄, the expression of the boundary point pₙ that determines each interval is expressed as a single bit difference. Therefore, common bit patterns can be easily extracted from each interval.

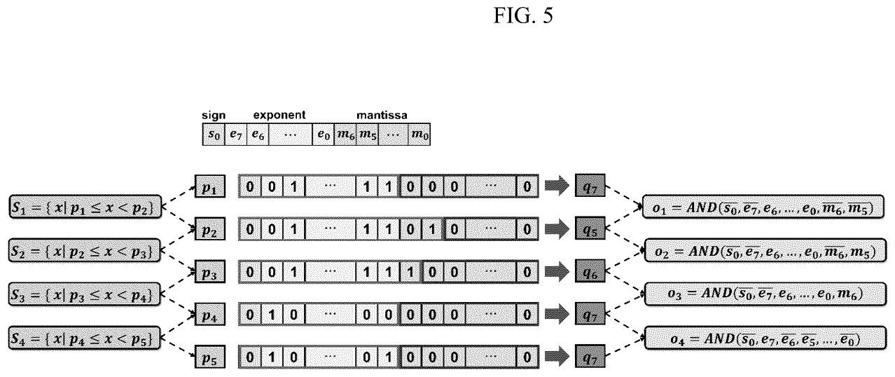

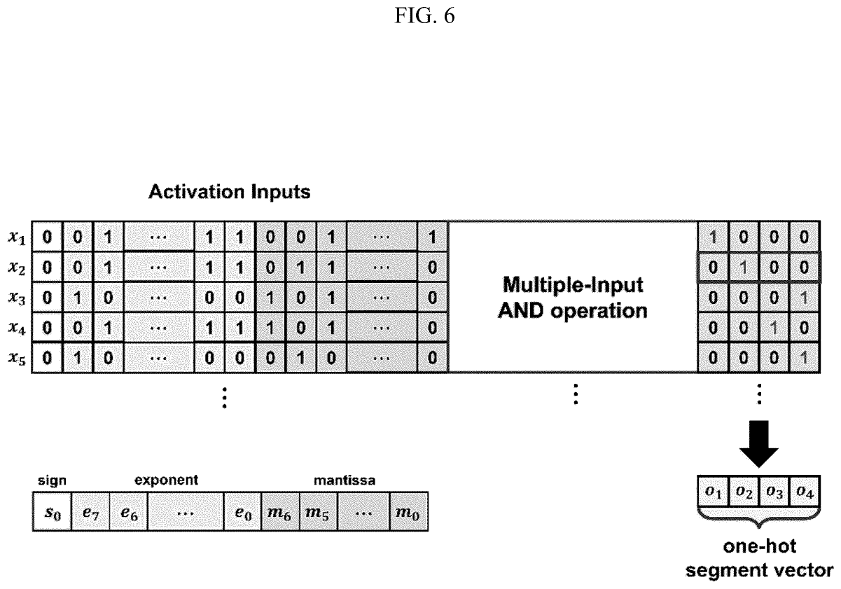

FIG. 5 shows a method for setting multiple interval detection operators for detecting intervals according to input values based on interval information, and FIG. 6 shows a method for obtaining an interval indicator indicating an interval corresponding to an input value using interval detection operators.

Referring to FIGS. 4 and 5, the range of each interval S₁ to S₄ is determined by the boundary points located adjacently among the multiple boundary points (p₁ to p₅). For example, the first interval S₁ is the interval between the first boundary point p₁ and the second boundary point p₂, and the second interval S₂ is the interval between the second boundary point p₂ and the third boundary point p₃. Accordingly, the interval to which the input value x belongs can be determined based on which of the multiple boundary points p₁ to p₅ the input value x is located between. Here, based on the unique floating point representation of each interval (Sₙ, where n={1, . . . , 4}), interval detection operators can be set to determine whether the input value x belongs to the corresponding interval.

The interval detection operators can be extracted as a unique common bit pattern from the floating point expressions that constitute each interval Sₙ, and can be set as an operator that performs an inversion (NOT) operation on the bit values of the input value x and a logical AND operation on the entire common bit pattern according to the bit value of the bit pattern. At this time, the inversion (NOT) operation may be performed on the bit whose bit value of the common bit pattern is 0, and the logical AND operation may be performed on the entire common bit pattern including the inverted bit.

The interval detection operators may consist of an inversion operator (NOT) and a logical AND operator (AND), which are set according to the bit length and bit value required for a unique floating point representation of each interval.

Specifically, to set up the interval detection operators, first, the number of bits of a common bit pattern required for a unique floating point representation in the first interval S₁ divided with the first boundary point p₁ and the second boundary point p₂ is checked, and the number of bits for the interval detection operation is specified.

Referring to FIG. 5, the area marked in green among the first boundary point p₁ and the second boundary point p₂ is the number of bits of the common bit pattern required for a unique floating point representation. While the first boundary point p₁ requires only the bits (1+8=9 bits) of the sine so and the exponent part e₇, . . . , e₀, the second boundary point p₂ requires two more bits m₆, m₅ in the mantissa part in addition to the bits of the sine so and the exponent part e₇, . . . , e₀. Therefore, based on the second boundary point p₂ where the interval detection operator requires relatively more bits to perform the interval detection operation, the number of bits (1+8+2=11 bits) including the sine so and the exponent e₇, . . . , e₀ and the 2-bit mantissa m₆, m₅ are set to be used for the interval detection operation. Here, the 11-bit common bit pattern of the first interval S₁ can be extracted as “0_01111111_00”.

In the second interval S₂, since the number of bits required for the second boundary point p₂ is greater than that for the third boundary point p₃, the number of bits for the interval detection operation may be set to 11 bits, and the 11-bit common bit pattern of the second interval S₂ may be extracted as “0_01111111_01”. In addition, in the third interval S₃, it may be set to 10 bits, and the 10-bit common bit pattern of the third interval S₃ may be extracted as “0_01111111_1”, and in the fourth interval S₄, it may be set to 9 bits, and the 9-bit common bit pattern of the fourth interval S₄ may be extracted as “0_10000000”.

The input value x belonging to a specific interval means that the input value x has the same bit pattern as the common bit pattern of the interval. Therefore, the interval detection operator may be composed of a logical AND operation on the input value x. However, since the logical AND operation outputs 1 only when all input values are 1, each interval detection operator may be configured so that the inversion (NOT) operation is performed first on the bit positions that have a value of 0 in the common bit pattern of the interval before the logical AND operation.

As an example, the interval detection operator for the first interval S₁ checks the bits (s₀, e₇, m₆, m₅) whose bit values are 0 among the 11 bits (0_01111111_00) that are the common bit patterns of the first interval S₁, and specifies an inversion operator (NOT) that inverts the bit values at the corresponding bit positions in the input value x. In addition, the interval detection operator for the second interval S₂ also checks the bits (s₀, e₇, m₆) whose bit value is 0 among the 11-bit common bit pattern (0_01111111_01), and specifies the inversion operator (NOT). In addition, in the interval detection operator for the third interval S₃, the inversion operator (NOT) is specified for the bits (s₀, e₇) whose bit value is 0 among the 10-bit common bit pattern (0_01111111_1). In addition, in the interval detection operator for the fourth inversion S₄, the inversion operator (NOT) is specified for the bits (s₀, e₆˜e₀) whose bit value is 0 among the 9-bit common bit pattern (0_10000000).

Once the number of bits of the interval detection operator for each interval Sₙ and the bit positions to which the inversion operator is to be applied are determined, an interval detection operator for each interval Sₙ to determine the interval to which the input value x belongs may be configured as shown on the right side of FIG. 5 by adding a logical AND operator (AND) for the determined number of bits.

Once multiple interval detection operators are configured for each interval Sₙ, the input interval determination module 20 may perform an interval detection operation on the input value x with each of the multiple interval detection operators, as shown in FIG. 6, to obtain multiple interval detection values o₁, o₂, o₃ and o₄.

That is, in the 11 bits consisting of the sine so and exponent e₇, . . . , e₀ of the input value x in the bf16 format and the 2-bit mantissa m₆ and m₅, the four bit values at the bit positions corresponding to (s₀, e₇, m₆, m₅) may be inverted (NOT), and then a logical AND operation (AND) may be performed on the entire 11 bits to obtain the interval detection value o₁ for the first interval S₁. Similarly, in 11 bits consisting of the sine so and exponent e₇, . . . , e₀ of the input value x and the 2-bit mantissa m₆ and m₅, the three bit values at the bit positions corresponding to (s₀, e₇, m₆) may be inverted (NOT) and then a logical AND operation may be performed on the entire 11 bits to obtain the interval detection value o₂ for the second interval S₂, and in 10 bits s₀, e₇, . . . , e₀, m₆, the bit values at the bit positions corresponding to (s₀, e₇) are inverted (NOT) and then a logical AND operation is performed to obtain the interval detection value o₃ for the third interval S₃. In addition, by performing an inversion operation (NOT) on the 8 bit values of the bit positions corresponding to (s₀, e₆, . . . , e₀) in 9 bits s₀, e₇, . . . , e₀ and then performing a logical AND operation (AND), the interval detection value o₄ for the 4th interval S₄ can be obtained.

When the input value x is operated with the interval operator for each interval, among the multiple interval detection values o₁, o₂, o₃ and o₄ calculated for each interval Sₙ, only the interval detection value for the interval to which the input value x belongs has a bit value of 1, and the rest all have bit values of 0. Therefore, the multiple calculated interval detection values o₁, o₂, o₃ and o₄ form an interval indicator O, which can also be called a one-hot segment vector that expresses the intervals in which the input value x is included in multiple intervals Sₙ by encoding them in a one-hot encoding manner.

As described above, the input interval determination module 20 sets multiple interval operators that perform bitwise operations on the input value x to determine the interval in which the input value x is included, and performs interval operations on the input value x with the set multiple interval operators to obtain a one-hot encoded interval indicators O. Accordingly, the input interval determination module 20 may also be called a BSE (Bitwise Segment Encoder).

Here, for the convenience of understanding, it is explained that the interval information acquisition module 10 acquires multiple boundary points having floating point representations as interval information, the input interval determination module 20 sets multiple interval operators based on the multiple boundary points acquired as interval information, and acquires interval indicators O using the set interval operators. However, in the trained artificial neural network, interval information for approximating the activation function with multiple approximate activation functions may be set in advance, and when the interval information is set, multiple interval operators can also be determined in advance according to the set interval information.

Therefore, the input interval determination module 20 may be configured to perform interval operations on the input value x by directly obtaining preset interval operators without setting multiple interval operators. In this case, the interval information acquisition module 10 can be omitted.

Meanwhile, the apparatus for accelerating activation function of the present disclosure can be implemented using PIM (Processing-in-memory) in which a plurality of input values x₁, . . . , x₅ are stored. In this case, the input interval determination module 20 may be configured to simultaneously perform a multi-input interval detection operation in parallel by performing a bit inversion and a logical AND operation for multiple inputs on multiple input values x₁, . . . , x₅ stored in a memory array under the control of a memory controller (not shown) as in FIG. 6, thereby obtaining multiple interval indicators O₁, . . . , O₅ representing each interval of the multiple input values x₁, . . . , x₅ at once. Accordingly, the computational cost can be reduced.

The approximate function acquisition module 30 acquires an approximate activation function of a specified interval according to an interval indicator acquired from the input interval determination module 20.

As described above, when an interval including an input value x is determined by an interval indicator O, an approximate activation function in which an activation function f is approximated by a linear function in the determined interval must be acquired. As shown in FIG. 3, since the interval-specific approximate activation function (fₙ′, where n={1, . . . , 4}) has already been set in the process of approximating the activation function f, the approximate function acquisition module 30 only needs to acquire the approximation function fₙ′ set in the determined interval n.

However, as described above, when the apparatus for accelerating activation function is implemented using PIM, the approximation function fₙ′ corresponding to the acquired multiple interval indicators Oᵢ for the multiple stored input values (xᵢ, where i is a natural number) must be identified and obtained, respectively. Accordingly, as the number i of input values xᵢ increases, the approximation function fₙ′ must be repeatedly acquired through the interval indicators frequently, which may lead to increased computational costs.

Meanwhile, since the approximate activation function approximated by linear interpolation in each interval has the form ax+b for the input value x, once the coefficient a and bias b of the approximate activation function fₙ′ are obtained, it can be considered that the approximate activation function has been obtained.

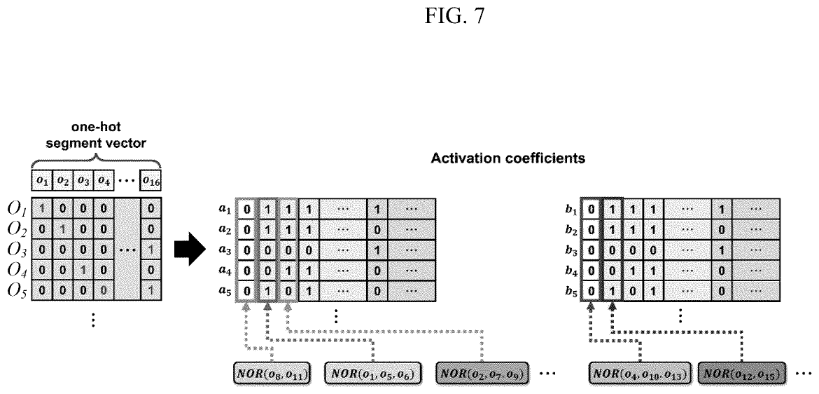

Accordingly, when the apparatus for accelerating activation function is implemented using PIM, the approximate function acquisition module 30 may be configured to simultaneously acquire coefficients a and biases b of multiple approximate activation functions fₙ′ in parallel as a bit combination of multiple interval indicators Oᵢ acquired for multiple input values xᵢ, as shown in FIG. 7.

FIG. 7 is a diagram for explaining a method for obtaining coefficients and biases of an approximate activation function based on an interval indicator.

In FIGS. 3 to 6, for the convenience of explanation, the case where the activation function f is divided into 4 intervals S₁ to S₄ is illustrated, but in FIG. 7, the case where the activation function f is divided into 16 intervals S₁ to S₁₆ is assumed, and accordingly, the one-hot encoded interval indicator Oᵢ has 16 interval detection values o₁ to o₁₆. That is, the interval indicator Oᵢ may be composed of 16-bit data. In addition, the interval indicator Oᵢ is obtained as many as the number i of input values xᵢ.

The approximate function acquisition module 30 implemented with PIM may logically combine the bits of each interval detection value o₁ to o₁₆ from multiple interval indicators Oᵢ stored in the memory under the control of a memory controller (not shown), and the values in the column direction in FIG. 7, so that the coefficients a and biases b of the approximate activation function fₙ′ corresponding to each of multiple input values xᵢ can be acquired together. At this time, the approximate function acquisition module 30 can obtain each bit value of multiple coefficients aᵢ and multiple biases bᵢ by performing an inverted logical OR operation (NOR) on each interval detection value o₁ to o₁₆ in the column direction designated by the memory controller.

In the example of FIG. 7, a case is illustrated in which a first bit of a coefficient aᵢ is obtained by performing an NOR operation on the bit values of the 8th bit o₈ and the 11th bit o₁₁ of multiple interval indicators Oᵢ each consisting of 16-bit interval detection values o₁ to o₁₆, and a second bit of a coefficient aᵢ is obtained by performing an NOR operation on the bit values of the 1st bit o₁, the 5th bit o₅, and the 6th bit o₆ of the interval indicator Oᵢ.

Similarly, a case is illustrated where an NOR operation is performed on the bit values of the 4th bit o₄, the 10th bit o₁₀, and the 13th bit o₁₃ of the interval indicator Oᵢ to obtain the first bit of the bias bᵢ, and an NOR operation is performed on the bit values of the 12th bit o₁₂ and the 15th bit o₁₅ of the interval indicator Oᵢ to obtain the second bit of the bias bᵢ.

At this time, the bits oₙ of the interval indicator Oᵢ for which an NOR operation must be performed to obtain each coefficient aᵢ and bias bᵢ may be specified by the memory controller using a lookup table, etc.

As illustrated in FIG. 7, when the approximate function acquisition module 30 simultaneously acquires the coefficients aᵢ and biases bᵢ of the approximate activation function fₙ′ for multiple input values xᵢ through parallel operation, the computational cost can be significantly reduced.

The approximate function acquisition module 30 receives and decodes an interval indicator encoded as a one-hot segment vector to acquire coefficients aᵢ and biases bᵢ of an approximate activation function fₙ′, and therefore may be referred to as a segment coefficient decoder (SCD).

The activation operation module 40 may perform an activation operation on an input value x using multiple input values xᵢ and the coefficients aᵢ and bias bᵢ of an approximate activation function fₙ′ obtained for each of the multiple input values xᵢ, and obtain the activation operation result as a kernel output y.

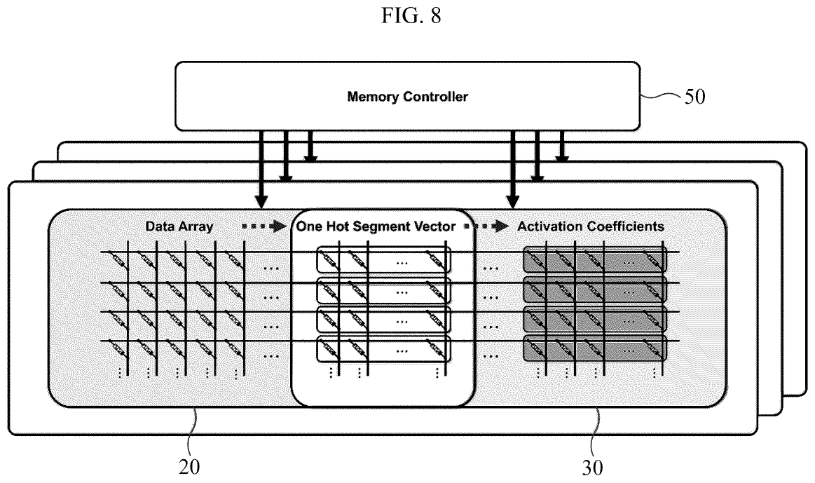

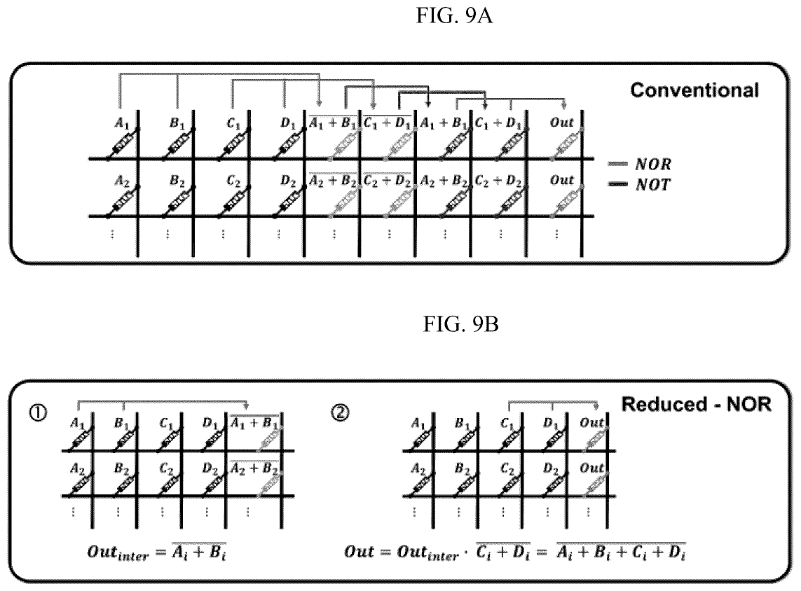

FIG. 8 shows an example of a PIM-based implementation of an apparatus for accelerating activation function, and FIG. 9 is a diagram for explaining a reduced-NOR operation in PIM.

As described above, the apparatus for accelerating activation function may be implemented with a digital PIM to reduce the computational cost associated with the increase in complexity of the activation function.

As shown in FIG. 8, when the apparatus for accelerating activation function is implemented with a digital PIM, the input interval determination module 20 and the approximate function acquisition module 30 may each be implemented as part of a memory array. In this case, the input interval determination module 20 may encode multiple input values xᵢ in parallel under the control of the memory controller 50 as described above to obtain multiple interval indicators Oᵢ in the form of a one-hot segment vector, and the obtained multiple interval indicators Oᵢ may be stored as they are in the memory array.

In addition, the activation operation module 40 may also obtain coefficients aᵢ and biases bᵢ of multiple approximate functions fₙ′ for multiple input values xᵢ by decoding multiple stored interval indicators Oᵢ in parallel under the control of the memory controller 50, and the obtained coefficients aᵢ and biases bᵢ of multiple approximate functions fₙ′ may also be stored in the memory array.

Accordingly, the activation operation module 40 may perform an activation function operation using multiple input values xᵢ stored in the memory array and coefficients aᵢ and biases bᵢ of multiple approximation functions fₙ′, and may store the kernel output y, which is the result of performing the activation function operation, back in the memory array.

In this way, since parallel processing for multiple inputs is possible based on the PIM operation, the throughput of the activation function operation can be greatly improved, and since the coefficients aᵢ and biases bᵢ are stored in the memory array, there is an advantage in that hardware for implementing a separate LUT is not required. In particular, since the coefficients aᵢ and biases bᵢ of the linearly approximated approximate activation function fₙ′ are stored in the memory array and parallel operations are performed, the computational cost can be greatly reduced while maintaining high accuracy compared to when the activation function f is approximated based on a polynomial.

In addition, when the apparatus for accelerating activation function is implemented with a non-volatile memory-based digital PIM, the computational cost can be further reduced by applying reduced-NOR operation.

As shown in FIG. 9A, in the past, when performing an NOR operation on multiple bit values Aᵢ, Bᵢ, Cᵢ and Dᵢ, first, an NOR operation was performed on two bit values (Aᵢ, Bᵢ), (Cᵢ, Dᵢ), the operation results (A̅ᵢ̅+̅B̅ᵢ̅, C̅ᵢ̅+̅D̅ᵢ̅) were stored in separate memory cells. Then, each of these was inverted (NOT) and stored in another memory cell. After that, an NOR operation was performed on the inverted operation results (Aᵢ+Bᵢ), (Cᵢ+Dᵢ) to obtain the operation result (out=A̅ᵢ̅+̅B̅ᵢ̅+̅C̅ᵢ̅+̅D̅ᵢ̅). Therefore, a total of five logical operations were required for the NOR operation on four bit values.

However, when the apparatus for accelerating activation function is implemented with a nonvolatile memory-based digital PIM such as a memristor, FeRAM (Ferroelectric RAM), MRAM (Magnetic RAM), and PRAM (Phase Change RAM), as shown in FIG. 9B, even if data is overlappingly written to a specific memory cell, the bit value of the same operation result may be written. Accordingly, as in \textcircled{1} of FIG. 9B, first, an NOR operation is performed on two bit values Aᵢ and Bᵢ and the result (A̅ᵢ̅+̅B̅ᵢ̅) is stored in a separate memory cell, and then an NOR operation is performed on the remaining two bit values Cᵢ and Dᵢ and the result (C̅ᵢ̅+̅D̅ᵢ̅) is overlappingly written to the memory cell where the previous result (A̅ᵢ̅+̅B̅ᵢ̅) is stored. At this time, if all of the results (C̅ᵢ̅+̅D̅ᵢ̅) that are recorded overlapping the previous results (A̅ᵢ̅+̅B̅ᵢ̅) are 0, 0 is recorded, whereas if even one has a value of 1, a value of 1 is recorded, so the amount of operations for multi-bit NOR operations can be greatly reduced. In addition, since no memory cells are required to store intermediate operation results, the usability of the memory can also be greatly improved.

However, this is a measure to further improve the operation performance of the apparatus for accelerating activation function of the present disclosure, and the apparatus for accelerating activation function does not have to be implemented with a non-volatile memory-based digital PIM.

In the illustrated embodiment, respective configurations may have different functions and capabilities in addition to those described above, and may include additional configurations in addition to those described above. In addition, in an embodiment, each configuration may be implemented using one or more physically separated devices, or may be implemented by one or more processors or a combination of one or more processors and software, and may not be clearly distinguished in specific operations unlike the illustrated example.

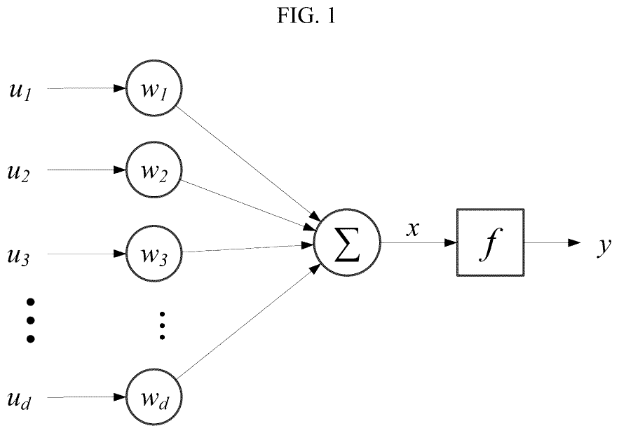

In addition, the apparatus for accelerating activation function shown in FIG. 1 may be implemented in a logic circuit by hardware, firm ware, software, or a combination thereof or may be implemented using a general purpose or special purpose computer. The apparatus may be implemented using hardwired device, field programmable gate array (FPGA) or application specific integrated circuit (ASIC). Further, the apparatus may be implemented by a system on chip (SoC) including one or more processors and a controller.

In addition, the apparatus for accelerating activation function may be mounted in a computing device or server provided with a hardware element as a software, a hardware, or a combination thereof. The computing device or server may refer to various devices including all or some of a communication device for communicating with various devices and wired/wireless communication networks such as a communication modem, a memory which stores data for executing programs, and a microprocessor which executes programs to perform operations and commands.

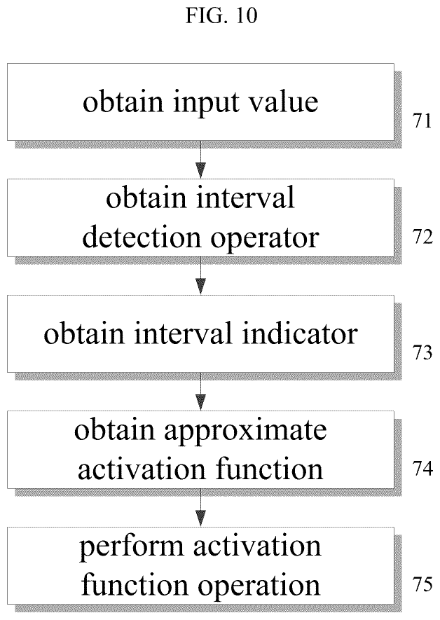

FIG. 10 shows a method for accelerating activation function according to one embodiment.

Referring to FIGS. 1 to 9B, the method for accelerating activation function of FIG. 10 will be described. First, an input value x, which is an operand on which an operation must be performed with an activation function, is obtained (71). Here, the input value x may be the result

$$( x = {\sum }_{j = 1}^{d} {u}_{j} {w}_{j} )$$

of a weighted sum of the weights w₁˜w_{d} for multiple values u₁˜u_{d} applied to the kernels provided in the artificial neural network, as described in FIG. 1. In addition, since the artificial neural network has multiple kernels, multiple input values xᵢ can be obtained from the multiple kernels.

Once the input value x is obtained, multiple interval detection operators are obtained to determine the interval in which the input value x is included in order to select one of the multiple approximate activation functions fₙ′ that linearly approximate the activation function f set for each kernel by dividing it into intervals (72). Here, the multiple interval detection operators may be composed of operators that invert and perform logical AND operations on some bits of the input value x according to the bit length and bit value used for the floating point representation of the boundary point pₙ that divides each interval, as shown in FIG. 4.

Once the multiple interval detection operators are obtained according to multiple divided intervals, an interval detection operation is performed on the input value x using the obtained interval detection operators to obtain an interval indicator O (73). Here, the interval indicator is composed of the result of performing an interval detection operation on the input value x using multiple interval detection operators, and may be obtained in the form of a one-hot segment vector.

Once the interval indicator O is obtained, the interval that includes the input value x is determined among the multiple intervals divided according to the obtained interval indicator O, and an approximate activation function that approximates the activation function in the determined interval is obtained (74). Since the approximate activation function for each interval is set in advance, when the interval that includes the input value x is determined, the approximate activation function can be easily obtained.

Then, by performing an activation function operation on the input value x using the obtained approximate activation function, the output y of the kernel is obtained (75).

Meanwhile, the method for accelerating activation function shown in FIG. 10 may be performed by an apparatus for accelerating activation function, and the apparatus for accelerating activation function may be implemented with a digital PIM. In the case where the apparatus for accelerating activation function is implemented with a digital PIM, as shown in FIG. 8, multiple input values xᵢ may already be acquired and stored in a memory array. In addition, in the process of approximating the activation function, the memory controller 50 may encode multiple input values xᵢ stored in the memory array in parallel according to the interval detection operator already set, and acquire multiple interval indicators Oᵢ together and store them in the memory array.

In addition, rather than individually searching and obtaining the approximate activation function for each of the multiple interval indicators Oᵢ stored in the memory array, the coefficients aᵢ and biases bᵢ that constitute the multiple approximated activation functions may be obtained as a combination of bitwise NORs of the multiple interval indicators Oᵢ and stored in the memory array, thereby further reducing the computational cost.

Additionally, when the apparatus for accelerating activation function is implemented as a nonvolatile memory-based digital PIM, the reduced-NOR operation shown in (b) of FIG. 9 may be applied to reduce computational cost as well as improve memory usage efficiency.

In FIG. 10, it is described that respective processes are sequentially executed, which is, however, illustrative, and those skilled in the art may apply various modifications and changes by changing the order illustrated in FIG. 10 or performing one or more processes in parallel or adding another process without departing from the essential gist of the exemplary embodiment of the present disclosure.

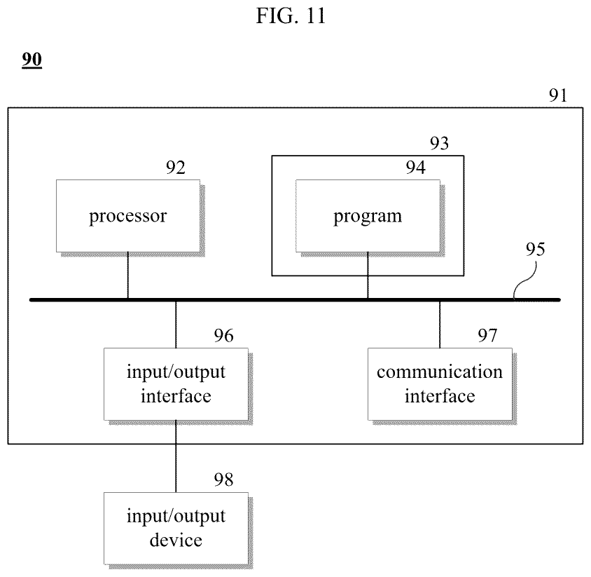

FIG. 11 is a diagram for explaining a computing environment including a computing device according to one embodiment.

In the illustrated embodiment, respective configurations may have different functions and capabilities in addition to those described below, and may include additional configurations in addition to those described below. The illustrated computing environment 90 may include a computing device 91 to perform the method for accelerating activation function illustrated in FIG. 10. In an embodiment, the computing device 91 may be one or more components included in the apparatus for accelerating activation function shown in FIG. 2.

The computing device 91 includes at least one processor 92, a computer readable storage medium 93 and a communication bus 95. The processor 92 may cause the computing device 91 to operate according to the above-mentioned exemplary embodiment. For example, the processor 92 may execute one or more programs 94 stored in the computer readable storage medium 93. The one or more programs 94 may include one or more computer executable instructions, and the computer executable instructions may be configured, when executed by the processor 92, to cause the computing device 91 to perform operations in accordance with the exemplary embodiment.

The communication bus 95 interconnects various other components of the computing device 91, including the processor 92 and the computer readable storage medium 93.

The computing device 91 may also include one or more input/output interfaces 96 and one or more communication interfaces 97 that provide interfaces for one or more input/output devices 98. The input/output interfaces 96 and the communication interfaces 97 are connected to the communication bus 95. The input/output devices 98 may be connected to other components of the computing device 91 through the input/output interface 96. Exemplary input/output devices 98 may include input devices such as a pointing device (such as a mouse or trackpad), keyboard, touch input device (such as a touchpad or touchscreen), voice or sound input device, sensor devices of various types and/or photography devices, and/or output devices such as a display device, printer, speaker and/or network card. The exemplary input/output device 98 is one component constituting the computing device 91, may be included inside the computing device 91, or may be connected to the computing device 91 as a separate device distinct from the computing device 91.

The present disclosure has been described in detail through a representative embodiment, but those of ordinary skill in the art to which the art pertains will appreciate that various modifications and other equivalent embodiments are possible from this. Therefore, the true technical protection scope of the present invention should be determined by the technical spirit set forth in the appended scope of claims.

What is claimed is:

1. An apparatus for accelerating activation function, comprising:
a memory; and
a controller,
wherein an application range of the activation function is divided into multiple intervals, and the controller
obtains an interval indicator indicating an interval in which an input value is included by using multiple interval detection operators to select one approximate activation function among multiple approximate activation functions approximated in each interval,
obtains an approximate activation function set for the interval designated by the interval indicator, and
inputs the input value into the obtained approximate activation function to obtain an activation operation result.

2. The apparatus for accelerating activation function according to claim 1,
wherein an interval detection operator is configured as an operator that inverts some bits of the input value and performs a logical AND operation according to a bit length and a bit value of a bit pattern that values included in each interval have in common, when the application range of the activation function is divided into the multiple intervals by multiple boundary points expressed in floating point numbers.

3. The apparatus for accelerating activation function according to claim 1,
wherein the interval indicator is a one-hot segment vector composed of a 1-bit interval detection value obtained by operating the input value with each of multiple interval operators for each interval.

4. The apparatus for accelerating activation function according to claim 1,
wherein the multiple approximate activation functions is obtained by
searching for a point where an error between the activation function and an approximate function in which the activation function is approximated by linear interpolation in the interval divided so far in the application range of the activation function is maximum,
setting points whose absolute value is a power of 2 among the closest points to the searched point as boundary points and adding the set boundary points to a boundary point list, and if the set boundary points are already included in the boundary point list, setting a midpoint between two closest power of 2 points to the searched point as a boundary point and adding the midpoint to the boundary point list, and if both the set boundary points and the midpoint are boundary points that are already included in the boundary point list, setting a midpoint between the closest point to the searched point in the boundary point list and the searched point as the boundary point and adding the midpoint to the boundary point list, and
linearly interpolating the activation function in each interval divided by multiple boundary points.

5. The apparatus for accelerating activation function according to claim 1,
wherein the apparatus for accelerating activation function is implemented with PIM (Processing-in-memory).

6. The apparatus for accelerating activation function according to claim 5,
wherein the controller obtains the interval indicator for each of multiple input values by performing an interval detection operation in parallel for each of the multiple input values stored in the memory using the multiple interval detection operators.

7. The apparatus for accelerating activation function according to claim 5,
wherein the controller obtains coefficients and biases of the multiple approximate activation functions selected by each of multiple interval indicators according to multiple input values by combining logical operations of bit values for each bit position of the multiple interval indicators stored in the memory.

8. The apparatus for accelerating activation function according to claim 7,
wherein the controller obtains the bit values for each bit position of the coefficients and the biases by performing NOR operations on the bit values for each bit position specified in the multiple interval indicators.

9. The apparatus for accelerating activation function according to claim 8,
wherein the apparatus for accelerating activation function is implemented with a nonvolatile memory-based PIM, and
the controller performs reduced-NOR operations that first performs and stores NOR operations on two bits when performing NOR operations on three or more multi-bits, and then overlaps and records NOR operations on the bit values of other bits.

10. The apparatus for accelerating activation function according to claim 1,
wherein input values are obtained by calculating a weighted sum of weights and at least one value applied to multiple kernels provided in an artificial neural network, respectively.

11. A method for accelerating activation function, which is performed by a controller in an apparatus including a memory and the controller, the method comprising the steps of:
obtaining an interval indicator indicating an interval in which an input value is included by using multiple interval detection operators to select one approximate activation function among multiple approximate activation functions approximated in each interval where an application range of the activation function is divided into multiple intervals;
obtaining an approximate activation function set for the interval designated by the interval indicator; and
inputting the input value into the obtained approximate activation function to obtain an activation operation result.

12. The method for accelerating activation function according to claim 11,
wherein an interval detection operator is configured as an operator that inverts some bits of the input value and performs a logical AND operation according to a bit length and a bit value of a bit pattern that values included in each interval have in common, when the application range of the activation function is divided into the multiple intervals by multiple boundary points expressed in floating point numbers.

13. The method for accelerating activation function according to claim 11,
wherein the interval indicator is a one-hot segment vector composed of a 1-bit interval detection value obtained by operating the input value with each of multiple interval operators for each interval.

14. The method for accelerating activation function according to claim 11,
wherein the multiple approximate activation functions is obtained by
searching for a point where an error between the activation function and an approximate function in which the activation function is approximated by linear interpolation in the interval divided so far in the application range of the activation function is maximum,
setting points whose absolute value is a power of 2 among the closest points to the searched point as boundary points and adding the set points to a boundary point list, and if the set points are already included in the boundary point list, setting a midpoint between two closest power of 2 points to the searched point as a boundary point and adding the midpoint to the boundary point list, and if both the set points and the midpoint are boundary points that are already included in the boundary point list, setting a midpoint between the closest point to the searched point in the boundary point list and the searched point as the boundary point and adding the midpoint to the boundary point list, and
linearly interpolating the activation function in each interval divided by multiple boundary points.

15. The method for accelerating activation function according to claim 11,
wherein the step of obtaining an interval indicator includes:
in the apparatus implemented with PIM, obtaining the interval indicator for each of multiple input values by performing an interval detection operation in parallel for each of the multiple input values stored in the memory using the multiple interval detection operators.

16. The method for accelerating activation function according to claim 15,
wherein the step of obtaining an approximate activation function includes:
obtaining coefficients and biases of the multiple approximate activation functions selected by each of multiple interval indicators according to the multiple input values by combining logical operations of bit values for each bit position of the multiple interval indicators stored in the memory.

17. The method for accelerating activation function according to claim 16,
wherein the step of obtaining an approximate activation function includes:
obtaining the bit values for each bit position of the coefficients and the biases by performing NOR operations on the bit values for each bit position specified in the multiple interval indicators.

18. The method for accelerating activation function according to claim 17,
wherein the step of obtaining an approximate activation function includes:
in the apparatus implemented with a nonvolatile memory-based PIM, performing reduced-NOR operations that first performs and stores NOR operations on two bits when performing NOR operations on three or more multi-bits, and then overlaps and records NOR operations on the bit values of other bits.

19. The method for accelerating activation function according to claim 11,
wherein input values are obtained by calculating a weighted sum of weights and at least one value applied to multiple kernels provided in an artificial neural network, respectively.
